(19) United States
(12) Patent Application Publication
(10) Pub. No.: US 2004/0178477 A1
(43) Pub. Date: Sep. 16, 2004

(54) Semiconductor wafer

(75) Inventor: Masakazu Nakabayashi, Hyogo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/653,286

(22) Filed: Sep. 3, 2003

(30) Foreign Application Priority Data
Mar. 14, 2003 (JP) 2003-069372(P)

(51) Int. Cl. H01L 23/544

(52) U.S. Cl. 257/620

(57) ABSTRACT

A semiconductor wafer is provided, where the crossing angle (θ) between an inclined surface and a first main surface ranges from 8 to 15 degrees. Similarly, the crossing angle (θ) between an inclined surface and a second main surface ranges from 8 to 15 degrees. Further, the chamfer width of the inclined surfaces is 200 micrometers. This configuration optimizes the shape of the circumferential end face portion of a semiconductor wafer, such that a semiconductor wafer can be provided with improved yield of semiconductor devices formed on a semiconductor wafer.

### BACKGROUND OF THE INVENTION

1. Field of the Invention

The present invention relates to a semiconductor wafer, and more particularly to shapes of the end face of a semiconductor wafer.

2. Description of the Background Art

A semiconductor wafer that is cut out from a cylindrical body of semiconductor crystal is used to form semiconductor devices on its surface. In the process of forming desired devices on a semiconductor wafer, the circumferential end face portion of the semiconductor wafer is tapered, rounded, or the like in order to prevent the occurrence of scratching, chipping, fracture, slipping and the like caused by various manufacturing equipment coming in contact with the periphery of the semiconductor wafer, as well as heat stress during annealing, and the like.

In practice, however, it has been found that employing the above-mentioned shape does not always provide a sufficient effect for precluding slipping and the like to provide improved yield of semiconductor devices formed on a semiconductor wafer.

### SUMMARY OF THE INVENTION

The present invention is directed to solving the problem mentioned above. An object of the present invention is to provide a semiconductor wafer which has the shape of the circumferential end face portion of a semiconductor wafer optimized to provide improved yield of semiconductor devices formed on a semiconductor wafer.

A semiconductor wafer according to the present invention has substantially a disk shape. The semiconductor wafer of the present invention includes a first main surface, a second main surface located at a side opposite to the first main surface, and an end face surrounding the circumference of the wafer. The semiconductor wafer has, in its cross-sectional shape when cut along its diameter, an inclined surface connecting the end face and at least one of the first and second main surfaces in the region where the end face traverses at least one of the first and second main surfaces. The crossing angle between the inclined surface and at least one of the first and second main surfaces traversing the inclined surface ranges from 8 to 15 degrees. The chamfer width, which is the length of the inclined surface projected against one of the first main surface and the second main surface traversing the inclined surface (hereinafter referred to as projection length of the inclined surface against the main surfaces), ranges from 70 to 230 micrometers.

Thus, by limiting in value the chamfer width and the crossing angle between the inclined surface(s) and the first main surface and the second main surface, an optimization of the shape of a semiconductor wafer is accomplished to prevent the occurrence of scratching, chipping, fracture, slipping and the like thereon, in order to provide improved yield of semiconductor devices formed on this semiconductor wafer effectively.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a perspective view illustrating the entire structure of a semiconductor wafer according to an embodiment of the invention.

FIG. 2 is a view in the direction of the arrow of II-II of FIG. 1.

FIG. 3 shows the result of measurements of the chamfer width (W1) and the yield (%).

FIG. 4 is a schematic view illustrating a method of manufacturing a semiconductor wafer according to an embodiment of the invention.

### DESCRIPTION OF THE PREFERRED EMBODIMENTS

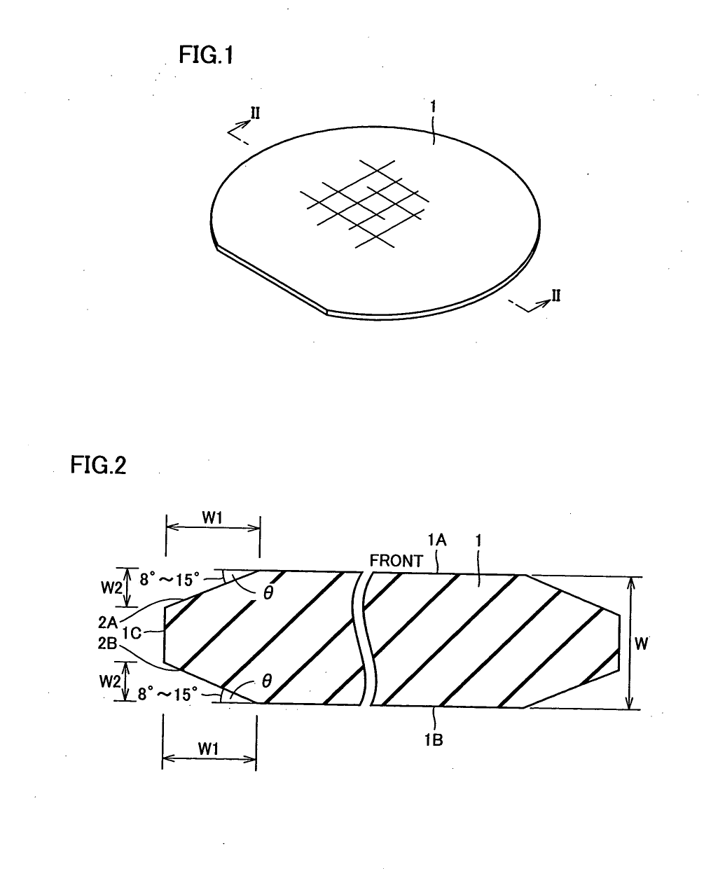

Referring now to FIGS. 1 and 2, a semiconductor wafer 1 will be described according to an embodiment of the present invention.

Referring to FIGS. 1 and 2, semiconductor wafer 1 according to an embodiment has substantially a disc-shape, which is cut out from a cylindrical body of semiconductor crystal, and includes a first main surface 1A, second main surface 1B located opposite to first main surface 1A, and an end face 1C surrounding the perimeter thereof

FIG. 2 shows a sectional shape of this semiconductor wafer 1 when cut along its diameter. Thus, since this semiconductor wafer 1 is substantially circular, the sectional shape when cut along its diameter (i.e. the surface perpendicular to first main surface 1A) has generally the same shape in any location (except the region where orientation flats are provided).

In the region where first main surface 1A traverses end face 1C, an inclined surface 2A is provided to connect first main surface 1A and end face 1C. Similarly, in the region where second main surface 1B traverses end face 1C, inclined surface 2B is provided to connect second main surface 1B and end face 1C. In the present embodiment, these inclined surfaces 2A, 2B are provided along the entire perimeter of the circumferential end face region of semiconductor wafer 1. The crossing angle (θ) between inclined surface 2A and first main surface 1A ranges from approximately 8 to 15 degrees. Similarly, the crossing angle (θ) between inclined surface 2B and second main surface 1B ranges from approximately 8 to 15 degrees.

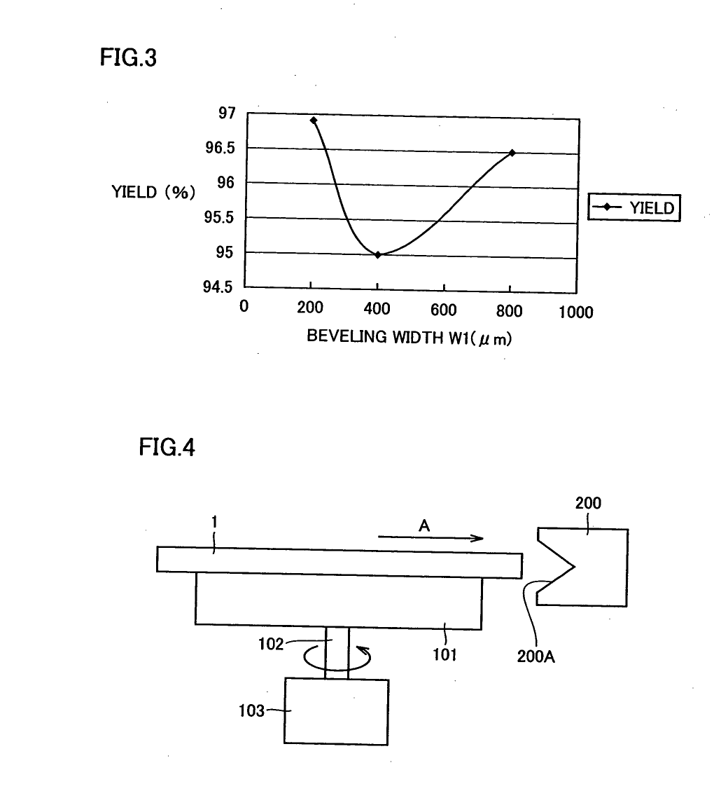

FIG. 3 represents the relation between the yield of semiconductor devices formed on this semiconductor wafer 1, and the chamfer width W1, which is the projection length of inclined surface 2A against first main surface 1A and the projection length of inclined surface 2B against second main surface 1B.

As shown in FIG. 3, the yield (%) presents the maximum of 96.8 when the chamfer width W1 is 200 micrometers, decreases until the chamfer width W1 is 400 micrometers, and has its minimum of 95 percent when the chamfer width W1 is 400 micrometers. As the chamfer width W1 further increases, the yield (%) gradually improves and reaches 96.5 percent when the chamfer width W1 is 800 micrometers.

A greater chamfer width W1, however, means a smaller area for semiconductor devices to be formed. Therefore a smaller chamfer width W1 is preferred. Accordingly, from the result of measurements shown in FIG. 3, a chamfer width W1 of 200 micrometers is determined to be optimal. The width of semiconductor wafer 1 (W) generally includes an error of −30 to +30 micrometers. Therefore, is is preferable to include an error of −30 to +30 micrometers for the chamfer width W1 as well.

Therefore, by setting the chamfer width W1 of semiconductor wafer 1 in the range of 170 to 230 micrometers in the case where the crossing angle (θ) between inclined surface 2A and first main surface 1A and between inclined surface 2B and second main surface 1B is set in the range of 8 to 15 degrees, the occurrence of scratching, chipping, fracture, slipping and the like on the semiconductor wafer can be minimized to maximize the yield of semiconductor devices formed on this semiconductor wafer 1.

It is to be appreciated that, while the present embodiment has inclined surfaces 2A, 2B defined by the range of the crossing angles and chamfer widths set forth above formed on both of main surfaces 1A and 1B, minimization of the occurrence of scratching, chipping, fracture, slipping and the like on a semiconductor wafer can also be achieved by having inclined surfaces 2A, 2B on any one of first main surface 1A and second main surface 1B.

FIG. 4 shows a method of manufacturing semiconductor wafer 1 having the shape described above. Semiconductor wafer 1 is placed on wafer chuck 101 including a rotator 103 and a rotator shaft 102. A polisher 200 is also provided with an inclined surface of a grinder 200A that take into account crossing angles and chamfer widths that define said inclined surface 2B. The circumferential end portion of semiconductor wafer 1 that is fixed on wafer chuck 101 and rotated is then pressed against the inclined surfaces of grinder 200A of polisher 200, thereby forming inclined surfaces 2A, 2B described above on circumferential end portion of semiconductor wafer 1. The chamfer width W1 of inclined surfaces 2A, 2B is adjusted by the feed rate of polisher 200 or semiconductor wafer 1. This feed rate is determined by the thickness (W) of semiconductor wafer 1.

As described above, semiconductor wafer 1 according to the present embodiment optimizes the shape of the circumferential end face portion of semiconductor wafer 1 by limiting in value the chamfer width (W1) and the crossing angle (θ) of inclined surfaces 2A, 2B with first main surface 1A and second main surface 1B. In this manner, the occurrence of scratching, chipping, fracture, slipping and the like on a semiconductor wafer is effectively minimized to provide improved yield of semiconductor devices formed on semiconductor wafer 1 according to the invention effectively.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor wafer having substantially a disc-shape including a first main surface, a second main surface located opposed to said first main surface, and an end face surrounding a perimeter thereof, said semiconductor wafer comprising:
in a sectional shape of said semiconductor wafer when cut along its diameter,
an inclined surface connecting said end face and at least one of said first main surface and said second main surface in a region where said end face traverses at least one of said first main surface and said second main surface,
wherein a crossing angle between said inclined surface and one of said first main surface and said second main surface traversing said inclined surface ranges from 8 to 15 degrees, and
a chamfer width corresponding to a projection length of said inclined surface against one of said first main surface and said second main surface traversing said inclined surface ranges from 170 to 230 micrometers.

2. A semiconductor wafer according to claim 1, wherein said chamfer width is 200 micrometers.

3. A semiconductor wafer according to claim 1, wherein said inclined surface is provided at both of a region where said first main surface traverses said end face, and a region where said second main surface traverses said end face.

4. A semiconductor wafer according to claim 1, wherein said inclined surface is provided along an entire perimeter surrounding said semiconductor wafer.
